(19) United States
(12) Patent Application Publication
(10) Pub. No.: US 2003/0038317 A1
(43) Pub. Date: Feb. 27, 2003

(54) Semiconductor device

(75) Inventors: Akinori kinugasa, Hyogo (JP); Shigeru Shiratake, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/200,250

(22) Filed: Jul. 23, 2002

(30) Foreign Application Priority Data
Aug. 27, 2001 (JP) 2001-255737 (P)

(51) Int. Cl. H01L 27/108; H01L 29/76; H01L 29/94; H01L 31/119

(52) U.S. Cl. 257/324; 257/368

(57) ABSTRACT

A silicon nitride film is formed above a semiconductor substrate so as to cover a gate electrode. Next, a silicon thermal oxidation film is formed on the surface of the silicon nitride film by carrying out thermal oxidation processing on the silicon nitride film. In the case that a pinhole exists in the silicon nitride film, the inside of the pinhole is also oxidized so as to be filled in with the silicon thermal oxidation film. Next, a silicon nitride film is formed by carrying out anisotropic etching on the silicon nitride film. After that, a contact hole is formed in the silicon oxide film, which is formed above the semiconductor substrate. A bit line contact part is formed within the contact hole and, then, a bit line is formed. Thereby, a semiconductor device is gained wherein an electrical short circuit can be prevented.

### BACKGROUND OF THE INVENTION

1. Field of the Invention

The present invention relates to a semiconductor device, in particular, to a semiconductor device for preventing an electrical short circuit.

2. Description of the Background Art

A dynamic random access memory (hereinafter referred to as “DRAM”) is described as an example of a semiconductor device according to a prior art. An exemplary memory cell of a DRAM is formed of one switching transistor T and one capacitor C as shown in FIG. 37. A word line 102 is connected to the gate of switching transistor T of the memory cell, a bit line 120 is connected to either the source or drain and capacitor C is connected to the other of the source or drain.

Next, an example of the structure in the vicinity of the switching transistor in the memory cell is described. As shown in FIG. 38, a gate electrode 102, which includes a polysilicon film 102a and a tungsten silicide film 102b, is formed above a semiconductor substrate 101 with a gate insulating film 110 intervening between the gate electrode and the semiconductor substrate. Here, source and drain regions (not shown) are formed, respectively, in a region located on each side of semiconductor substrate 101 with gate electrode 102 placed in between.

A silicon nitride film 103 is formed on gate electrode 102. A silicon nitride film 104 is formed as a sidewall insulating film on the sides of silicon nitride film 103 and of gate electrode 102. A silicon oxide film 106 is formed above semiconductor substrate 101 so as to cover silicon nitride film 104.

A bit line contact part 120, which is electrically connected to the source or drain region, is formed in silicon oxide film 106. A bit line 121, which is electrically connected to bit line contact part 120, is formed on silicon oxide film 106. The portion in the vicinity of a switching transistor in the memory cell of the DRAM according to a prior art is formed as described above.

In the above described DRAM according to the prior art, however, there is a problem point, which is shown in the following. Silicon nitride film 104, which is located on the sides of gate electrode 102 as a sidewall insulating film, is formed by carrying out anisotropic etching on the silicon nitride film, which is formed above semiconductor substrate 101 so as to cover gate electrode 102 and silicon nitride film 103.

At the time when this silicon nitride film 104 is formed, a pinhole 111 may be formed in silicon nitride film 104, as shown in FIG. 38, due to an air bubble, moisture or a foreign substance that occurs in silicon nitride film 104.

Due to the existence of such a pinhole 111, there may be a portion A where silicon nitride film 104, which is positioned between pinhole 111 and gate electrode 102, is partially thinner. In the case that bit line contact part 120 is formed under such a condition, an electric field can be easily generated in portion A where the silicon nitride film has become thinner.

Therefore, an electrical short circuit (arrow 130) may be caused between gate electrode 102 and bit line 120 via this portion A in this silicon nitride film 104, as shown in FIG. 37. In addition, in the case that pinhole 111 is comparatively large, an electrical semiconductor device may be caused directly between gate electrode 102 and bit line contact part 120. As a result, a problem arises wherein the DRAM cannot be operated as desired.

### SUMMARY OF THE INVENTION

The present invention is provided to solve the above problem point and the purpose thereof is to provide a semiconductor device for preventing an electrical short circuit.

A semiconductor device according to the present invention is provided with a first electrode part, a first insulating film, a second insulating film, an opening, a second conductive part and a short circuit prevention part. A first conductive part has a side and a top surface formed on the main surface of a semiconductor substrate. The first insulating film is formed so as to cover the side and the top surface of the first conductive part. The second insulating film is formed above the semiconductor substrate so as to cover the first insulating film and has an etching characteristic different from that of the first insulating film. The space of the opening overlaps, in a plane, the first insulating film and the opening is formed in the second insulating film so as to expose the surface of the semiconductor substrate. The second conductive part is formed within the opening. A process is carried out on the first insulating film so as to prevent a cavity from substantially penetrating through the area between the first conductive part and the second conductive part and, thereby, an electrical short circuit between the first conductive part and the second conductive part is avoided.

According to this structure, a process is carried out on the first insulating film so as to prevent a cavity from substantially penetrating through the area between the first conductive part and the second conductive part. Thereby, for example, a pinhole, which is formed at the time of the formation of the first insulating film, is prevented from penetrating through the area between the first conductive part and the second conductive part so that an electrical short circuit between the first conductive part and the second conductive part is avoided. As a result, the electrical operation of the semiconductor device becomes stable.

The first insulating film is preferably formed of, at least, two layers.

In this case, a pinhole that is formed in the first layer of the first insulating film may be covered by the second layer. Thereby, the formation of a comparatively large pinhole that reaches a portion of the first insulating film in the vicinity of the first conductive part to a portion of the first insulating film in the vicinity of the second conductive part can be prevented so that an electrical short circuit between the first conductive part and the second conductive part can be effectively avoided.

In addition, a thermal oxidation part is preferably included that is formed by carrying out thermal oxidation processing on the first insulating film.

Thereby, the thermal oxidation part is located between the first conductive part and the second conductive part so that the withstanding property of insulation is increased between the first conductive part and the second conductive part and an electrical short circuit between them can be avoided without fail.

Furthermore, the thermal oxidation part is preferably formed within a pinhole in the case that the pinhole exists in the first insulating film as a cavity.

In this case, even when a portion located between the pinhole and the first conductive part has been formed wherein the first insulating film is partially thinner, the occurrence of an electrical field in the vicinity of the pinhole portion can be prevented by filling the thermal oxidation part into the pinhole.

In addition, the thermal oxidation part preferably includes a surface thermal oxidation part located on the surface of the first insulating film.

Thereby, the surface thermal oxidation part is located between the first conductive part and the second conductive part, in addition to the first insulating film, so that the withstanding property of insulation between the first conductive part and the second conductive part further increases and, furthermore, an electrical short circuit between them is avoided without fail.

Preferably, the first conductive part includes a gate electrode and the second conductive part includes a bit line contact part.

In this case, the stability of the electrical operation of the semiconductor device, which has a memory element such as a DRAM, is improved.

As for more concrete description of types of films, the first insulating film is a silicon nitride film and the second insulating film is a silicon oxide film.

In this case, the silicon oxide film alone can be etched, without substantially etching the silicon nitride film, so that the opening can be easily formed in a self-aligned manner.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view showing one step of a process for a semiconductor device according to a first embodiment of the present invention;

FIG. 2 is a cross sectional view showing the step that is carried out after the step shown in FIG. 1 according to the first embodiment;

FIG. 3 is a cross sectional view showing the step that is carried out after the step shown in FIG. 2 according to the first embodiment;

FIG. 4 is a cross sectional view showing the step that is carried out after the step shown in FIG. 3 according to the first embodiment;

FIG. 5 is a cross sectional view showing the step that is carried out after the step shown in FIG. 4 according to the first embodiment;

FIG. 6 is a cross sectional view showing the step that is carried out after the step shown in FIG. 5 according to the first embodiment;

FIG. 7 is a cross sectional view showing the step that is carried out after the step shown in FIG. 6 according to the first embodiment;

FIG. 8 is a cross sectional view showing one step for describing the improvement of the withstanding property of insulation according to the first embodiment;

FIG. 9 is a cross sectional view showing the step that is carried out after the step shown in FIG. 8 for describing the improvement of the withstanding property of insulation according to the first embodiment;

FIG. 10 is a cross sectional view showing one step of a process for a semiconductor device according to a second embodiment of the present invention;

FIG. 11 is a cross sectional view showing the step that is carried out after the step shown in FIG. 10 according to the second embodiment;

FIG. 12 is a cross sectional view showing the step that is carried out after the step shown in FIG. 11 according to the second embodiment;

FIG. 13 is a cross sectional view showing the step that is carried out after the step shown in FIG. 12 according to the second embodiment;

FIG. 14 is a cross sectional view showing the step that is carried out after the step shown in FIG. 13 according to the second embodiment;

FIG. 15 is a cross sectional view showing the step that is carried out after the step shown in FIG. 14 according to the second embodiment;

FIG. 16 is a cross sectional view showing one step for describing the improvement of the withstanding property of insulation according to the second embodiment;

FIG. 17 is a cross sectional view showing the step that is carried out after the step shown in FIG. 16 for describing the improvement of the withstanding property of insulation according to the second embodiment;

FIG. 18 is a cross sectional view showing one step of a process for a semiconductor device according to a third embodiment of the present invention;

FIG. 19 is a cross sectional view showing the step that is carried out after the step shown in FIG. 18 according to the third embodiment;

FIG. 20 is a cross sectional view showing the step that is carried out after the step shown in FIG. 19 according to the third embodiment;

FIG. 21 is a cross sectional view showing one step for describing the improvement of the withstanding property of insulation according to the third embodiment;

FIG. 22 is a cross sectional view showing the step that is carried out after the step shown in FIG. 21 for describing the improvement of the withstanding property of insulation according to the third embodiment;

FIG. 23 is a cross sectional view showing one step of a process for a semiconductor device according to a fourth embodiment of the present invention;

FIG. 24 is a cross sectional view showing the step that is carried out after the step shown in FIG. 23 according to the fourth embodiment;

FIG. 25 is a cross sectional view showing the step that is carried out after the step shown in FIG. 24 according to the fourth embodiment;

FIG. 26 is a cross sectional view showing the step that is carried out after the step shown in FIG. 25 according to the fourth embodiment;

FIG. 27 is a cross sectional view showing the step that is carried out after the step shown in FIG. 26 according to the fourth embodiment;

FIG. 28 is a cross sectional view showing the step that is carried out after the step shown in FIG. 27 according to the fourth embodiment;

FIG. 29 is a cross sectional view showing the step that is carried out after the step shown in FIG. 28 according to the fourth embodiment;

FIG. 30 is a cross sectional view showing one step for describing the improvement of the withstanding property of insulation according to the fourth embodiment;

FIG. 31 is a cross sectional view showing the step that is carried out after the step shown in FIG. 30 for describing the improvement of the withstanding property of insulation according to the fourth embodiment;

FIG. 32 is a cross sectional view showing one step according to a modified example of the fourth embodiment;

FIG. 33 is a cross sectional view showing one step of a process for a semiconductor device according to a fifth embodiment of the present invention;

FIG. 34 is a cross sectional view showing the step that is carried out after the step shown in FIG. 33 according to the fifth embodiment;

FIG. 35 is a cross sectional view showing one step of a process for a semiconductor device according to a sixth embodiment of the present invention;

FIG. 36 is a cross sectional view showing the step that is carried out after the step shown in FIG. 35 according to the sixth embodiment;

FIG. 37 is a diagram showing an equivalent circuit of a memory cell in a DRAM; and

FIG. 38 is a cross sectional view of a DRAM according to a prior art.

### DESCRIPTION OF THE PREFERRED EMBODIMENTS

First Embodiment

A manufacturing method of a DRAM according to a first embodiment of the present invention and a semiconductor device gained by this manufacturing method are described. First, as shown in FIG. 1, a polysilicon film and a tungsten silicide film, which become, for example, a gate electrode, are formed in sequence above semiconductor substrate 1 with a gate insulating film 10 intervening between the semiconductor substrate and the gate electrode. A silicon nitride film is formed on the tungsten silicide film by means of, for example, a CVD (chemical vapor deposition) method. A predetermined resist pattern (not shown) is formed on the silicon nitride film so that anisotropic etching is carried out on the silicon nitride film by using the resist pattern as a mask and, thereby, a silicon nitride film 3, which becomes a mask material for patterning the gate electrodes, is formed.

Anisotropic etching is sequentially carried out on the tungsten silicon film and on the polysilicon film by using silicon nitride film 3 as a mask and, thereby, a gate electrode 2 that includes a polysilicon film 2a and a tungsten silicon film 2b is formed. Next, a silicon nitride film 4 is formed above the semiconductor substrate 1 so as to cover silicon nitride film 3 and gate electrode 2 by means of, for example, a CVD method.

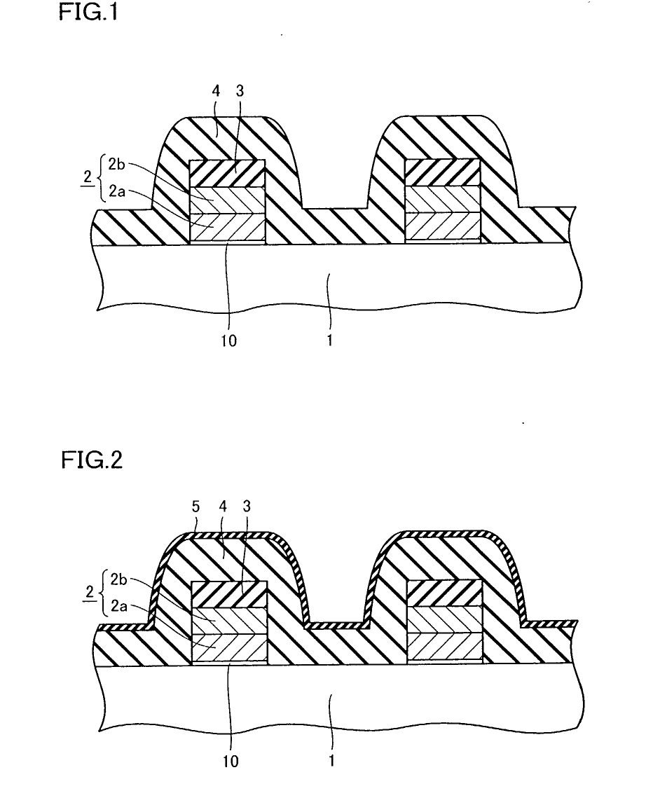

Next, as shown in FIG. 2, a silicon thermal oxidation film 5 is formed on the surface of silicon nitride film 4 by carrying out thermal oxidation processing on silicon nitride film 4. At this time, in the case that a pinhole exists in silicon nitride film 4 as described below, the inside of the pinhole is also oxidized so as to be filled in with the silicon thermal oxidation film.

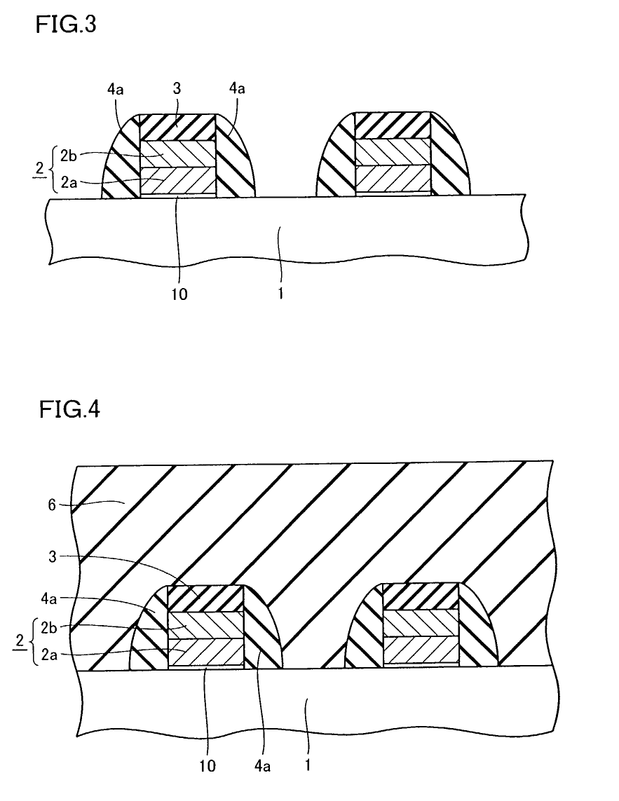

Next, as shown in FIG. 3, anisotropic etching is carried out on the entirety of the surface of silicon nitride film 4 that is covered by silicon thermal oxidation film 5 and, thereby, a silicon nitride film 4a is formed as a sidewall insulating film on the sides of gate electrode 2 and of silicon nitride film 3.

Next, as shown in FIG. 4, a silicon oxide film 6, such as a BPTEOS (boro phospho tetra ethyl ortho silicate glass) film, of which the etching characteristic is different from that of the silicon nitride film, is formed above semiconductor substrate 1 so as to cover silicon nitride films 4a, 3 and gate electrode 2 by means of a CVD method.

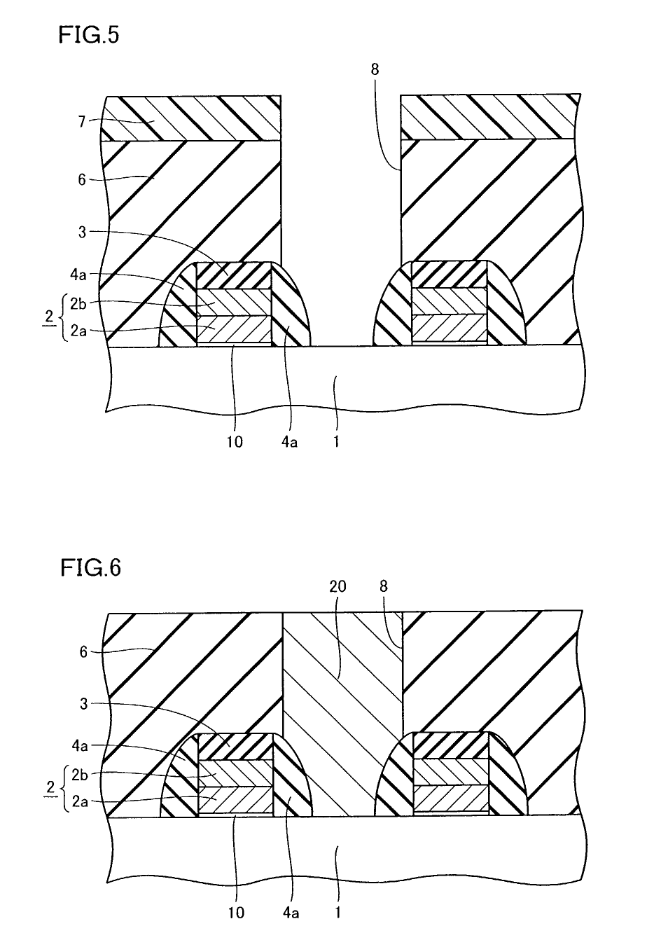

Next, as shown in FIG. 5, a predetermined resist pattern 7 is formed on silicon oxide film 6. Anisotropic etching is carried out on silicon oxide film 6 by using resist pattern 7 as a mask and, thereby, a contact hole 8 is formed so as to expose the surface of silicon substrate 1. After that, resist pattern 7 is removed.

Here, contact hole 8 is arranged so that the space thereof overlaps, in a plane, silicon nitride film 4a. Therefore, silicon oxide film 6 is etched while silicon nitride film 4a is not substantially etched so that contact hole 8 is easily formed in a self-aligned manner.

Next, a doped polysilicon film (not shown) is formed on silicon oxide film 6 by means of, for example, a CVD method so as to fill in contact hole 8. After that, as shown in FIG. 6, anisotropic etching is carried out on the entirety of the surface of the doped polysilicon film and the doped polysilicon film that is located on the top surface of silicon oxide film 6 is removed and, thereby, a bit line contact part 20 is formed by leaving the doped polysilicon film within contact hole 8.

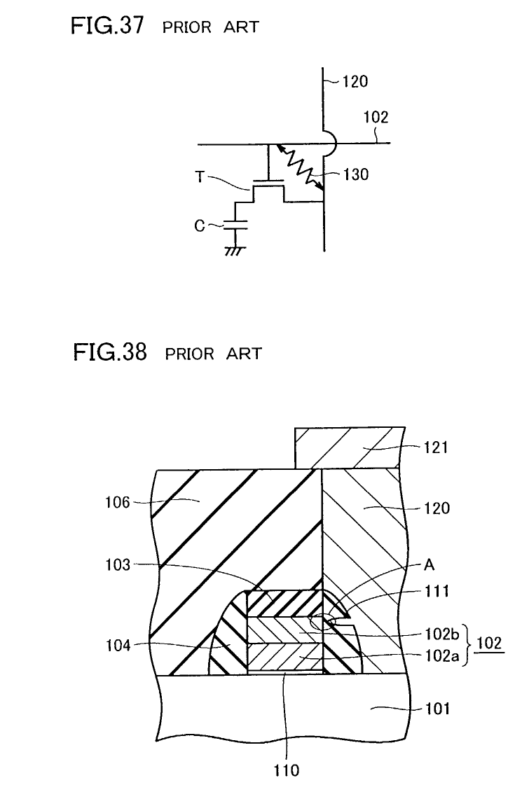

Next, as shown in FIG. 7, a bit line 21, which is electrically connected to bit line contact part 20, is formed on silicon oxide film 6. Thereby, the main parts of the transistor of the memory cell are formed. After that, metal wires, and the like, (not shown) that electrically connect the capacitors and respective memory cells are formed in this DRAM. Here, the equivalent circuit of the memory cell is the same as the circuit shown in FIG. 37.

In the above described manufacturing method of a DRAM, silicon nitride film 4a that is formed on the sides of gate electrode 2 as a sidewall insulating film is formed by carrying out anisotropic etching on silicon nitride film 4 that is formed so as to cover gate electrode 2, and the like, as shown in FIG. 1.

At the time when silicon nitride film 4 is formed in the step shown in FIG. 1 as described above, a pinhole may occur in silicon nitride film 4 due to an air bubble, moisture or a foreign substrate generated in silicon nitride film 4. Silicon nitride film 4 has a film property that is comparatively hard in comparison with other insulating films such as a silicon oxide film. Therefore, this pinhole rarely receives the effects from subsequent processing steps and remains unchanged in silicon nitride film 4 as a pinhole.

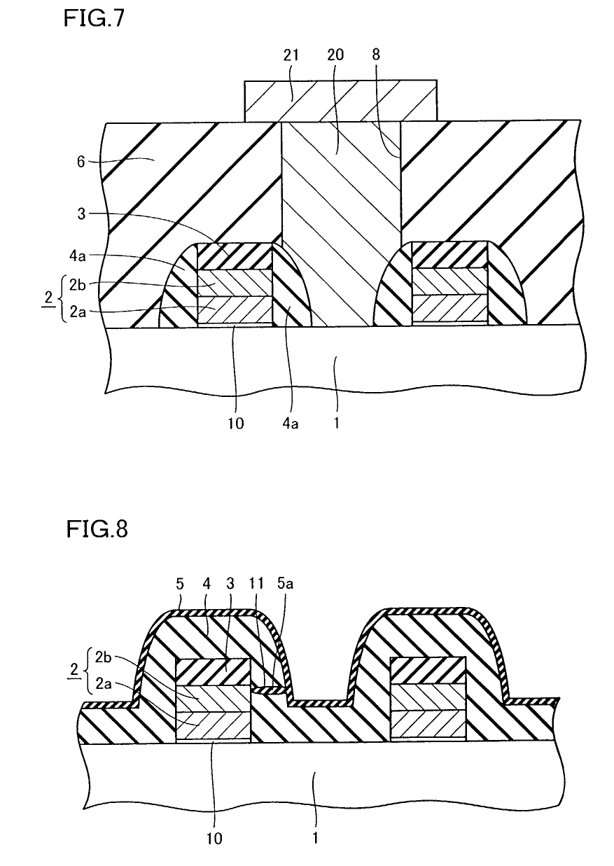

Therefore, as shown in FIG. 2, thermal oxidation processing is carried out after the formation of silicon nitride film 4. By carrying out the thermal oxidation processing, a silicon thermal oxidation film is formed on the surface of silicon nitride film 4 as shown in FIG. 8 and in the case that a pinhole 11 is present in silicon nitride film 4, the inside of pinhole 11 is filled in with a silicon thermal oxidation film 5a.

After this thermal oxidation processing, the above described respective processes shown in FIGS. 3 to 7 are carried out on the semiconductor substrate under the condition where the inside of pinhole 11 is filled in with silicon thermal oxidation film 5a.

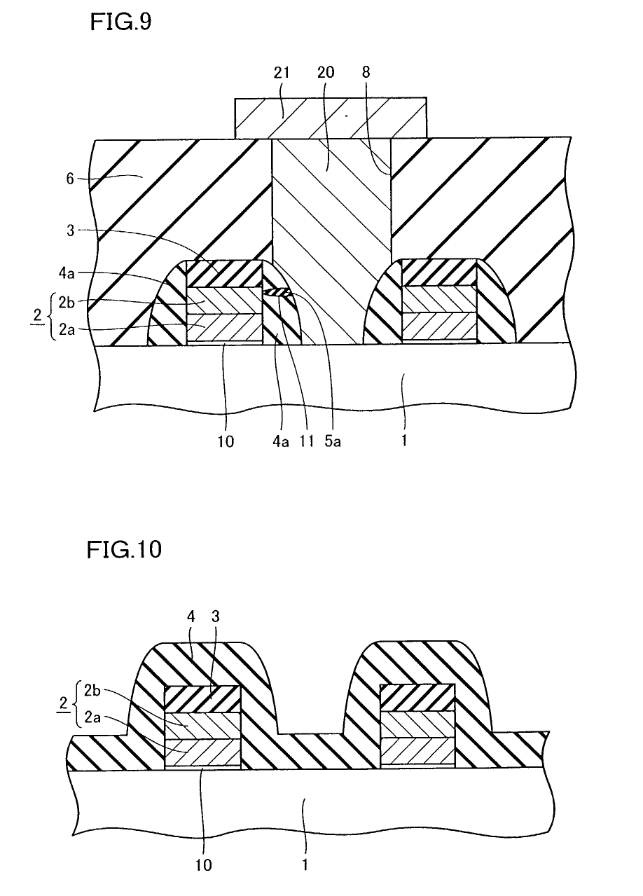

Then, as shown in FIG. 9, at the stage where a bit line 21 is formed, the condition is maintained wherein the inside of pinhole 11, which remains in silicon nitride film 4a, is filled in with silicon thermal oxidation film 5a.

Thereby, even in the case that a portion A located between pinhole 111 and gate electrode 102 is formed wherein silicon nitride film 104 is partially thinner in the conventional DRAM shown in FIG. 38, the inside of pinhole 11 is filled in with silicon thermal oxidation film 5a in the present semiconductor device so that the occurrence of an electrical field can be prevented in the vicinity of the pinhole 11 portion.

As a result, an electrical short circuit between gate electrode 2 and bit line 21 via bit line contact part 20 can be prevented so that a DRAM that can carry out a desired operation without fail can be gained.

Second Embodiment

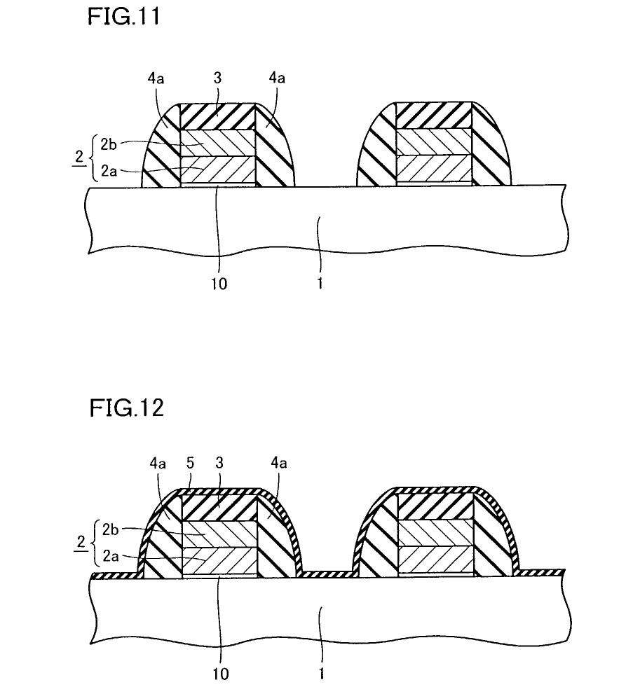

A manufacturing method of a DRAM according to a second embodiment of the present invention and a semiconductor device gained by this manufacturing method are described. Through a step similar to the step shown in FIG. 1 described above, a silicon nitride film 4 is formed above semiconductor substrate 1 so as to cover gate electrode 2, and the like, as shown in FIG. 10. Next, as shown in FIG. 11, a silicon nitride film 4a is formed on the sides of gate electrode 2 and of silicon nitride film 3 as a sidewall insulating film by carrying out anisotropic etching on the entirety of the surface of silicon nitride film 4.

Next, as shown in FIG. 12, a silicon thermal oxidation film 5 is formed on the surface of silicon nitride films 4a, 3 by carrying out thermal oxidation processing on silicon nitride films 4a, 3. At this time, as for a pinhole remaining in silicon nitride film 4, the inside of the pinhole is also oxidized so as to be filled in with the silicon thermal oxidation film as described below.

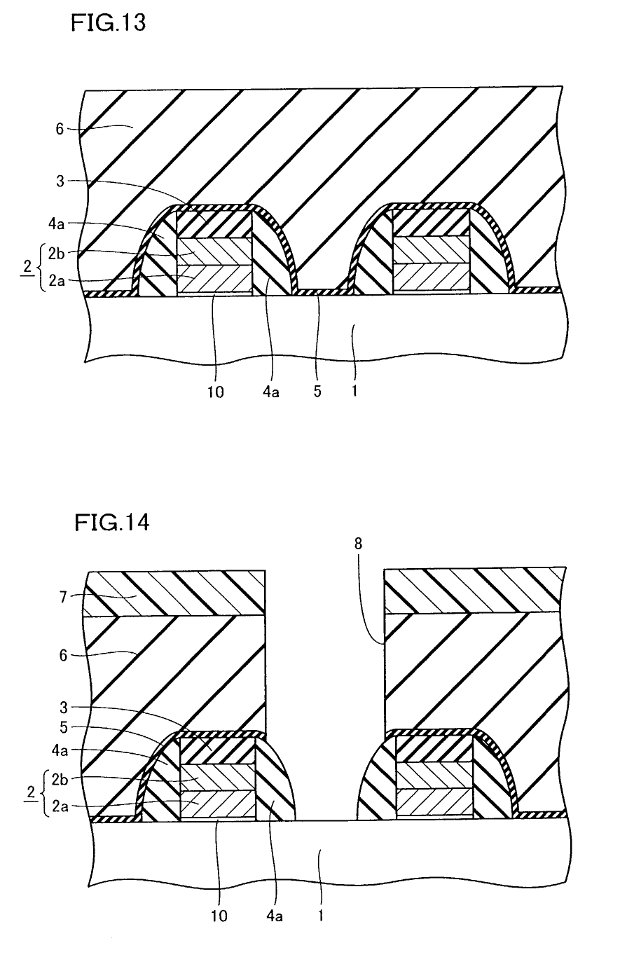

Next, as shown in FIG. 13, a silicon oxide film 6, such as a BPTEOS film, of which the etching characteristic is different from that of silicon nitride film 4a, is formed on semiconductor substrate 1 by means of a CVD method so as to cover silicon thermal oxidation film 5.

Next, as shown in FIG. 14, a predetermined resist pattern 7 is formed on silicon oxide film 6. By carrying out anisotropic etching on silicon oxide film 6 by using resist pattern 7 as a mask, a contact hole 6 is formed so as to expose the surface of silicon substrate 1. After that, resist pattern 7 is removed.

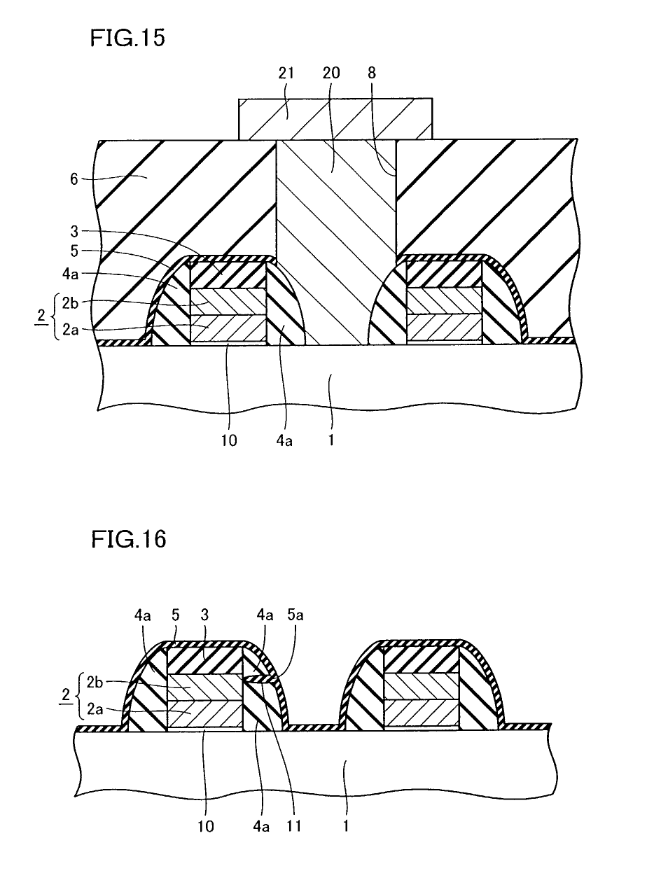

After that, by carrying out similar processes as in the steps shown in the above described FIGS. 6 and 7, a bit line contact part 20 and a bit line 21 are formed. Thereby, as shown in FIG. 15, the major parts of the transistor of the memory cell are formed.

In the above described manufacturing method of a DRAM, as shown in FIG. 16, even in the case that a pinhole occurs in silicon nitride film 4 at the time of the formation of silicon nitride film 4, the inside of the pinhole is filled in with silicon thermal oxidation film 5a by carrying out thermal oxidation processing after the formation of silicon nitride film 4a.

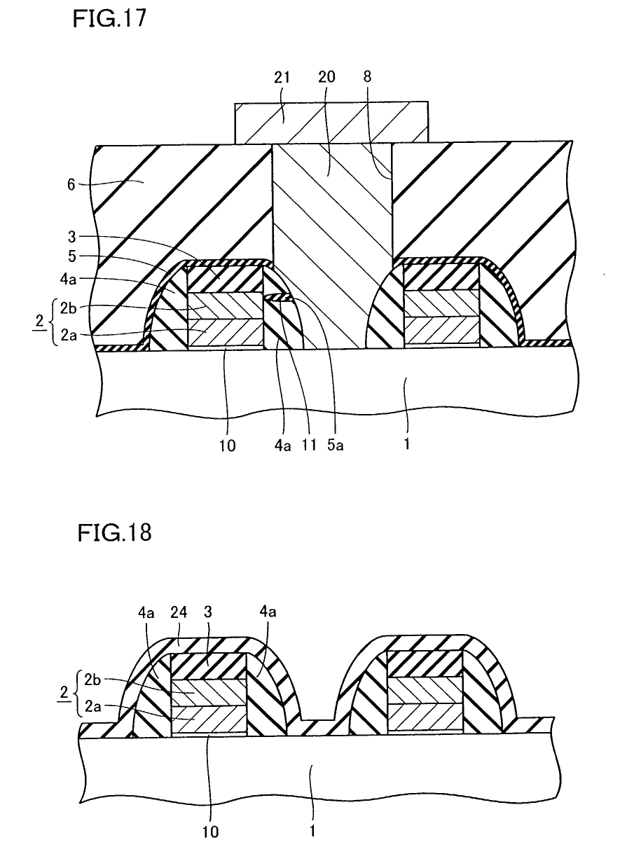

Thereby, as shown in FIG. 17, the inside of pinhole 11 is filled in with silicon thermal oxidation film 5a in the present semiconductor device so that, as has already been described, the occurrence of an electrical field in the vicinity of the pinhole 11 portion can be prevented. As a result, an electrical short circuit between gate electrode 2 and bit line 21 via bit line contact part 20 can be prevented so as to gain a DRAM that can carry out a desired operation without fail.

According to the above described first embodiment, thermal oxidation processing is carried out after the formation of silicon nitride film 4 and before carrying out anisotropic etching on the entirety of the surface of silicon nitride film 4. In this case, depending on the shape of the pinhole that has occurred at the time of the formation of silicon nitride film 4, a portion deep in the pinhole is assumed to remain in the condition of a cavity without being filled in with a silicon oxide film through the thermal oxidation processing.

In such a case, there is a risk that the cavity portion of the pinhole may be exposed at the time when anisotropic etching is carried out on the entirety of the surface of silicon nitride film 4. In the case that a bit line contact part is formed under such a condition, it is assumed that an electrical field occurs, in the same manner as in a conventional DRAM, in a portion located between pinhole 11 and gate electrode 2 wherein silicon nitride film 4a is partially thinner so that an electrical short circuit is caused between gate electrode 2 and bit line 21 via bit line contact part 20.

Contrarily, in the above described process, thermal oxidation processing is carried out on silicon nitride film 4a after the formation of silicon nitride film 4a as a sidewall insulating film and, thereby, silicon thermal oxidation film 5a is formed, without fail, inside of pinhole 11, which remains in silicon nitride film 4a as shown in FIG. 17, so that the pinhole that is not filled in with the silicon thermal oxidation film is not exposed.

As a result, an electrical short circuit between gate electrode 2 and bit line 21 can be prevented without fail.

Third Embodiment

A manufacturing method of a DRAM according to a third embodiment of the present invention and a semiconductor device gained by this manufacturing method are described. After passing through steps similar to the steps shown in the above described FIGS. 10 and 11, a silicon nitride film 24 is additionally formed on semiconductor substrate 1 by means of, for example, a CVD method so as to cover silicon nitride films 4a, 3, as shown in FIG. 18.

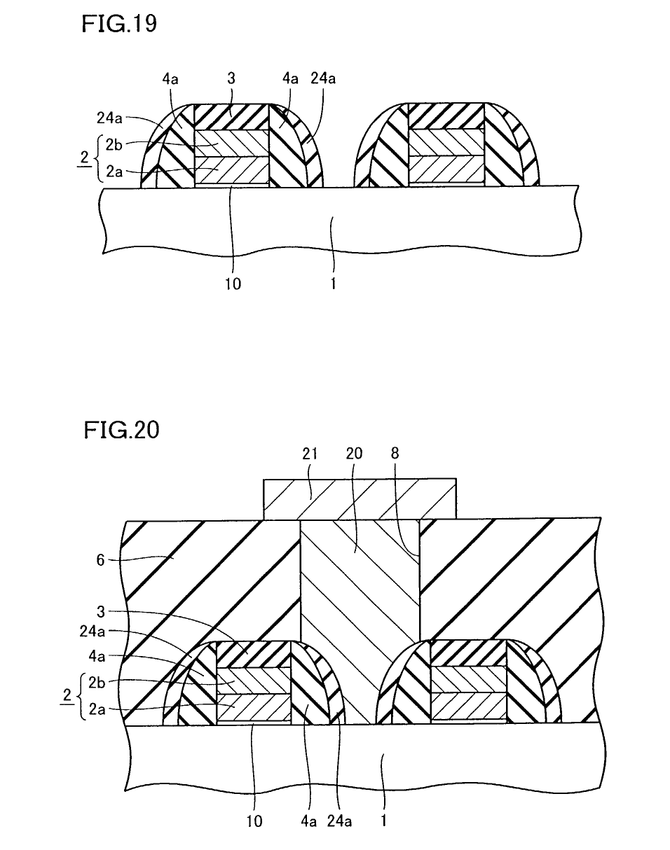

Next, as shown in FIG. 19, by carrying out anisotropic etching on the entirety of the surface of silicon nitride film 24, a silicon nitride film 24a is additionally formed on the surface of silicon nitride film 4a as a sidewall insulating film.

After that, by carrying out similar processes as in the steps shown in the above described FIGS. 4 to 7, a bit line contact part 20 and a bit line 21 are formed, as shown in FIG. 20. Thereby, the major parts of the transistor of the memory cell are formed.

In the above described manufacturing method of a DRAM, as shown in FIG. 18, an additional silicon nitride film 24 is formed so as to cover silicon nitride film 4a after the formation of silicon nitride film 4a.

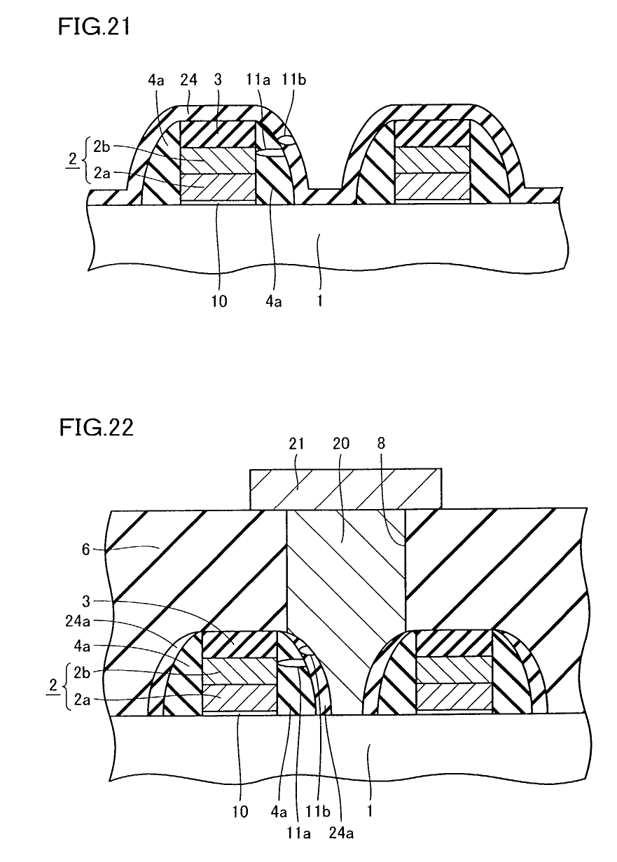

Thereby, as shown in FIG. 21, even in the case that, in the present semiconductor device, a pinhole that has occurred at the time of the formation of silicon nitride film 4 remains as pinhole 11a in silicon nitride film 4a, which is a sidewall insulating film, pinhole 11a is sealed up through the formation of silicon nitride film 24.

In addition, pinhole 11b, which has occurred at the time of formation of silicon nitride film 24, and pinhole 11a, which remains in silicon nitride film 4a, are not connected so that the formation of a comparatively large pinhole can be prevented.

Thereby, as shown in FIG. 22, a pinhole reaching from a portion of silicon nitride film 4a in the vicinity of gate electrode 2 to a portion of silicon nitride film 24a in the vicinity bit line contact part 20 is not formed so that the pinhole can be prevented from penetrating through the area between gate electrode 2 and bit line contact part 20.

As a result, an electrical short circuit between gate electrode 2 and bit line 21 via bit line contact part 20 can be prevented so as to gain a DRAM that can carry out a desired operation without fail.

Fourth Embodiment

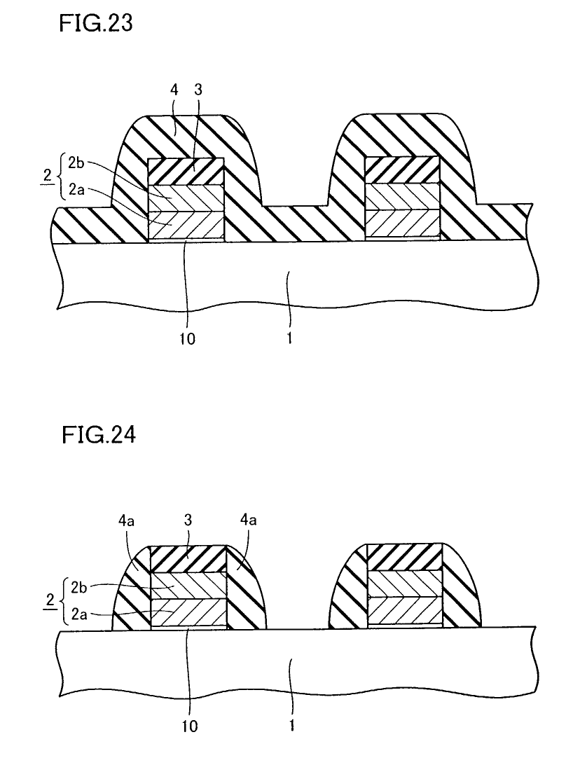

A manufacturing method of a DRAM according to a fourth embodiment of the present invention and a semiconductor device gained by this manufacturing method are described. Through a step similar to the step shown in the above described FIG. 1, a silicon nitride film 4 is formed above semiconductor substrate 1 so as to cover gate electrode 2, and the like, as shown in FIG. 23.

Next, as shown in FIG. 24, a silicon nitride film 4a is formed on the sides of gate electrode 2 and of silicon nitride film 3 as a sidewall insulating film by carrying out anisotropic etching on the entirety of the surface of silicon nitride film 4.

After that, as shown in FIG. 25, a silicon oxide film 6, such as a BPTEOS film, of which the etching characteristic is different from that of silicon nitride films 4a, 3, is formed above semiconductor substrate 1 so as to cover silicon nitride film 4a, 3 and gate electrode 2. A predetermined resist pattern 7 is formed on silicon oxide film 6.

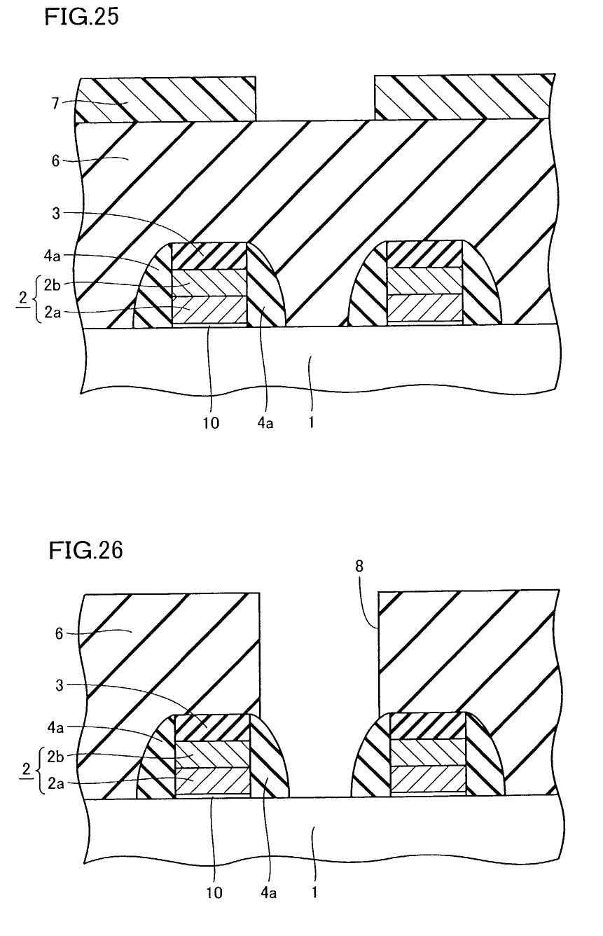

Next, as shown in FIG. 26, a contact hole 8 is formed so as to expose the surface of silicon substrate 1 by carrying out anisotropic etching on silicon oxide film 6 by using resist pattern 7 as a mask.

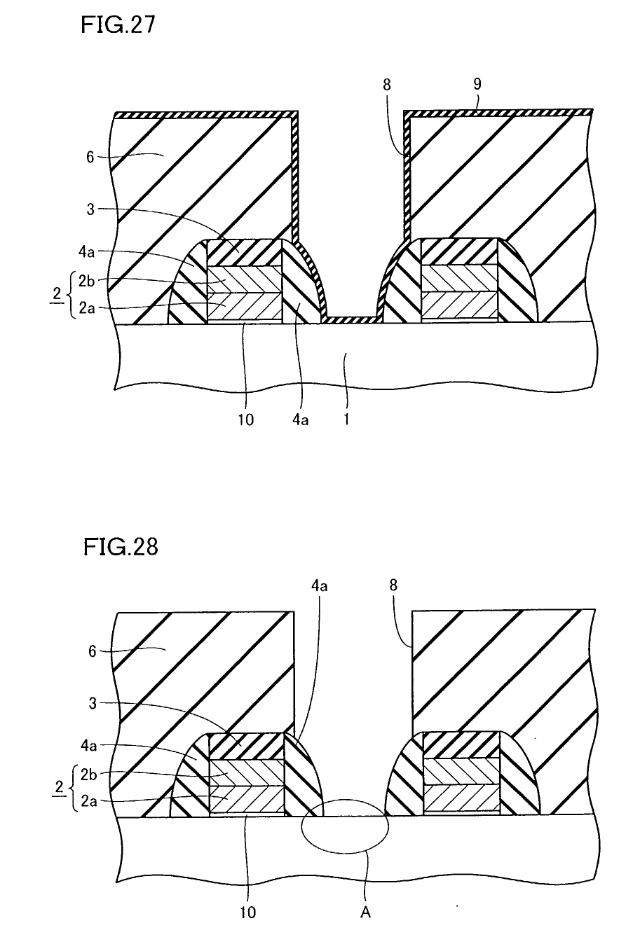

Next, as shown in FIG. 27, a silicon thermal oxidation film 9 is formed on the surface of silicon oxide film 6 and on the surface of silicon nitride film 4a, including on the surface within contact hole 8, by carrying out thermal oxidation processing. At this time, in the case that a pinhole remains in the exposed silicon nitride film 4a, as described below, the inside of the pinhole is oxidized so as to be filled in with the silicon thermal oxidation film.

Next, as shown in FIG. 28, the surface of the region of semiconductor substrate 1 located at the bottom of contact hole 8 is exposed by removing silicon thermal oxidation film 9 formed on the surface of silicon nitride film 4a, and the like, by, for example, carrying out wet etching.

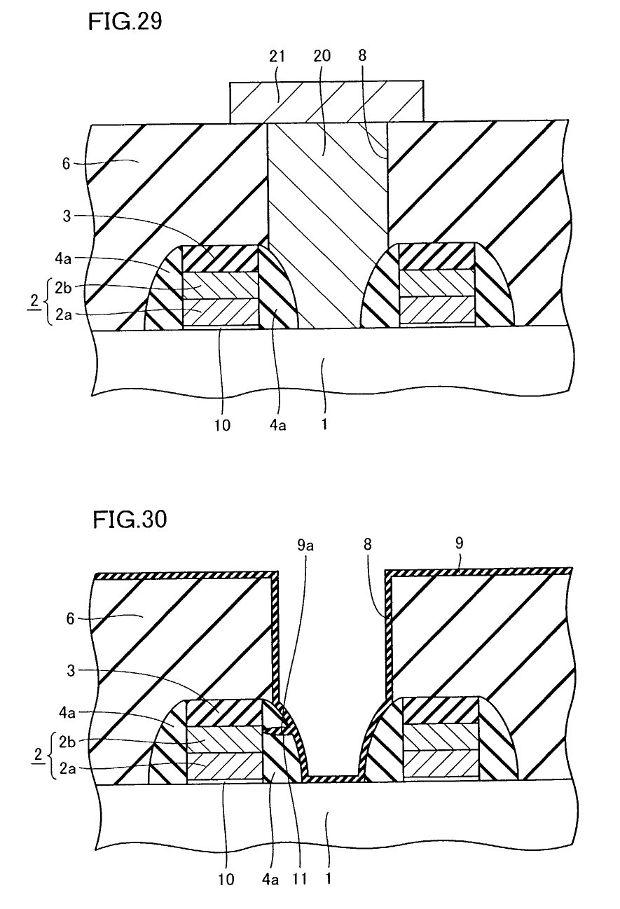

After that, a bit line contact part 20 and a bit line 21 are formed by carrying out processing similar to as in the steps shown in the above described FIGS. 6 and 7. Thereby, as shown in FIG. 29, the major parts of the transistor of the memory cell are formed.

In the above described manufacturing method of a DRAM, as shown in FIG. 30, even in the case that a pinhole occurs in silicon nitride film 4 at the time of the formation of silicon nitride film 4, the inside of pinhole 11 that remains in the exposed silicon nitride film 4a is filled in with silicon thermal oxidation film 9a by carrying out thermal oxidation processing after the formation of contact hole 8. In addition, silicon oxide film 9a that is formed within pinhole 11 is not removed at the time when silicon thermal oxidation film 9 is removed.

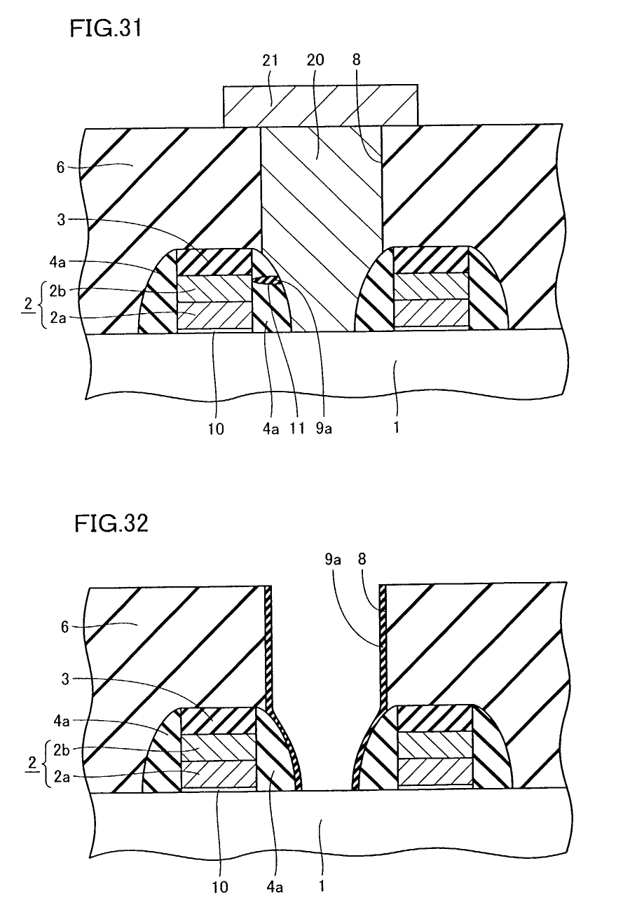

Thereby, as shown in FIG. 31, the inside of pinhole 11 is filled in with silicon thermal oxidation film 9a and, thereby, as has already been described, the occurrence of an electrical field in the vicinity of the pinhole 11 portion can be prevented. As a result, an electrical short circuit between gate electrode 2 and bit line 21 via bit line contact part 20 can be prevented so as to gain a DRAM that can carry out a desired operation without fail.

Here, though in the embodiment a case where silicon thermal oxidation film 9 is removed through wet etching in the step shown in FIG. 28 is described, the surface of semiconductor substrate 1 may be exposed at the bottom of contact hole 8 by carrying out anisotropic etching as shown in FIG. 32.

In this case, portions of silicon thermal oxidation film 9 that are located on the surface of the semiconductor substrate or on the top surface of silicon oxide film 6 are removed while portions of silicon thermal oxidation film 9 that are located on the surface of silicon nitride film 4a and on the sides of silicon oxide film 6 are not removed to a great degree and remain.

Thereby, silicon thermal oxidation film 9 intervenes between bit line contact part 20 and silicon nitride film 4a so that the withstanding property of insulation can be increased between bit line contact part 20 and gate electrode 2.

Fifth Embodiment

A manufacturing method of a DRAM according to a fifth embodiment of the present invention and a semiconductor device gained by this manufacturing method are described. Here, a process is described that is gained by combining the process where thermal oxidation processing is carried out on the silicon nitride film as described in the second embodiment and the process where two layers of silicon nitride film are formed as described in the third embodiment.

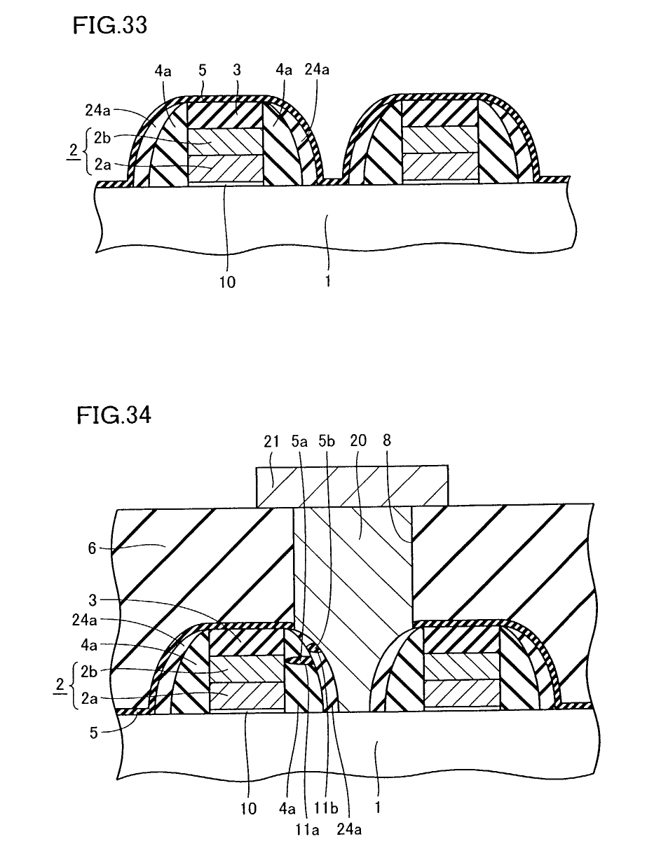

First, after the step shown in the above described FIG. 19, a silicon thermal oxidation film 5 is formed on the surface of silicon nitride films 24a, 3, and the like, by carrying out thermal oxidation processing as shown in FIG. 33.

After that, by carrying out processing similar to the steps shown in the above described FIGS. 4 to 7, a bit line contact part 20 and a bit line 21 are formed as shown in FIG. 34. Thereby, the major parts of the transistor of the memory cell are formed.

In the above described manufacturing method of a DRAM, as shown in FIG. 33, an additional silicon nitride film 24a is formed on silicon nitride film 4a. Thereby, even in the case that the pinhole that has occurred at the time of the formation of silicon nitride film 4 remains as pinhole 11a in silicon nitride film 4a, which is a sidewall insulating film, pinhole 11a is sealed up through the formation of silicon nitride film 24a.

Then, even in the case that the pinhole that has occurred at the time of the formation of silicon nitride film 24a remains as a pinhole 11b, a silicon thermal oxidation film 5b is formed inside of pinhole 11b by carrying out thermal oxidation processing after silicon nitride film 24a has been formed so that silicon thermal oxidation film 5a is formed within pinhole 11a.

In addition, at the time when silicon thermal oxidation film 5, which is exposed within the contact hole, is removed through, for example, wet etching, silicon thermal oxidation film 5a formed within pinhole 11b is not removed. Furthermore, the contact resistance between semiconductor substrate 1 and bit line contact part 20 can be reduced by removing silicon thermal oxidation film 5.

As described above, the withstanding property of insulation between bit line contact part 20 and gate electrode 2 is improved and an electrical short circuit between gate electrode 2 and bit line 21 via bit line contact part 20 can be prevented without fail so that a DRAM that can carry out a desired operation without fail is gained.

Sixth Embodiment

A manufacturing method of a DRAM according to a sixth embodiment of the present invention and a semiconductor device gained by this manufacturing method are described. Here, a process is described that is gained by combining the process where two layers of silicon nitride film are formed as described in the third embodiment and the process where thermal oxidation processing is carried out on the silicon nitride film after the opening of the bit line contact hole as described in the fourth embodiment.

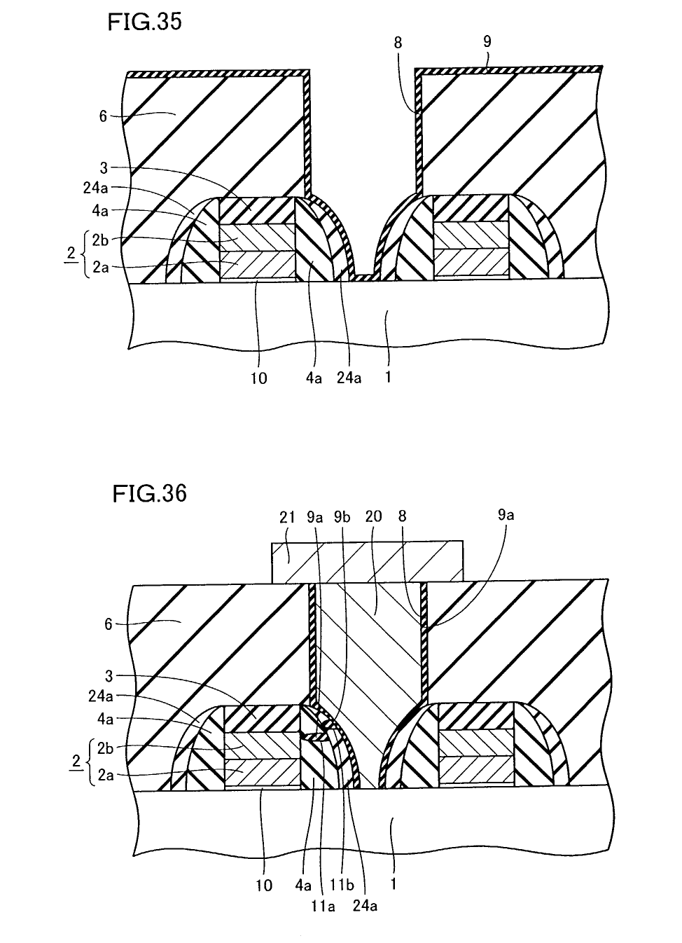

First, through the steps shown in the above described FIGS. 18 and 19, a contact hole 8 is formed in silicon oxide film 6 in the step shown in FIG. 20 and, after that, a thermal oxidation film 9 is formed on the surface of silicon oxide film 6 and on the surface of silicon nitride film 24a, including on the surface within contact hole 8, by carrying out thermal oxidation processing as shown in FIG. 35.

Next, as shown in FIG. 36, the surface of semiconductor substrate 1 is exposed at the bottom of contact hole 8 by carrying out anisotropic etching on the entirety of the surface of thermal oxidation film 9. After that, a bit line contact part 20 and a bit line 20 are formed. Thereby, the major parts of the transistor of the memory cell are formed.

In the above described method for a DRAM, as shown in FIG. 35, an additional silicon nitride film 24a is formed on silicon nitride film 4a. Thereby, even in the case that the pinhole that has occurred at the time of the formation of silicon nitride film 4 remains as pinhole 11a in silicon nitride film 4a, which is a sidewall insulating film, pinhole 11a is sealed up through the formation of silicon nitride film 24a.

Then, even in the case that the pinhole that has occurred at the time of the formation of silicon nitride film 24a remains as pinhole 11b, silicon thermal oxidation film 5b is formed within pinhole 11b by carrying out thermal oxidation processing on silicon nitride film 24a, and the like, after the formation of contact hole 8 so that silicon thermal oxidation film 5a is formed within pinhole 11a.

In addition, anisotropic etching is carried out on silicon thermal oxidation film 9 that is formed within contact hole 8 so that semiconductor substrate 1 is exposed at the bottom of contact hole 8 and, thereby, a portion 9a of silicon thermal oxidation film 9 remains on the surface of silicon nitride film 24a.

As described above, the withstanding property of insulation between bit line contact part 20 and gate electrode 2 is improved and an electrical short circuit between gate electrode 2 and bit line 21 via bit line contact part 20 can be prevented without fail so that a DRAM that can carry out a desired operation without fail is gained.

In general, an accelerated evaluation (burn-in) is carried out for a DRAM in order to detect, in advance, defects that cannot be discovered through a conventional inspection. There are some cases where the defects cannot be specified even when the defects are recognized in such an accelerated evaluation and defect analysis is carried out on the DRAM. In particular, the above described electrical short circuit between the gate electrode and the bit line contact part is regarded as a defect mode that is difficult to discover in a practical device.

As described in each embodiment, respectively, an electrical short circuit due to a pinhole that is considered to be a cause of a defect can be effectively avoided in a process for a semiconductor device according to the present invention.

Here, in each of the above described embodiments a DRAM is cited as an example and is described as a semiconductor device. However, the invention is not limited to a DRAM but, rather, may be a semiconductor device such as an SRAM so long as it is a semiconductor device that has one conductive part, such as a gate electrode, and a predetermined insulating film that covers this conductive part as well as an interlayer insulating film that covers this predetermined insulating film and is provided with another conductive part, such as a contact part that is formed in the interlayer insulating film so as to overlap, in a plane, a predetermined insulating film, at least.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising:
a first conductive part having a side and a top surface formed in a main surface of a semiconductor substrate;
a first insulating film formed so as to cover said side and said top surface of said first conductive part;
a second insulating film formed above said semiconductor substrate so as to cover said first insulating film, of which the etching characteristic is different from that of said first insulating film;
an opening formed in said second insulating film so as to expose a surface of said semiconductor substrate, of which the space overlaps, in a plane, said first insulating film; and
a second conductive part formed within said opening; wherein
an electrical short circuit between said first conductive part and said second conductive part is avoided by carrying out processing on said first insulating film in order to prevent a cavity from substantially penetrating through the area between said first conductive part and said second conductive part.

2. The semiconductor device according to claim 1, wherein said first insulating film comprises, at least, two layers.

3. The semiconductor device according to claim 1, further comprising a thermal oxidation part formed by carrying out thermal oxidation processing on said first insulating film.

4. The semiconductor device according to claim 3, wherein said thermal oxidation part is formed within a pinhole in the case that said pinhole exists in said first insulating film as said cavity.

5. The semiconductor device according to claim 3, wherein said thermal oxidation part includes a surface thermal oxidation part formed on the surface of said first insulating film.

6. The semiconductor device according to claim 1, wherein said first conductive part includes a gate electrode and, wherein said second conductive part includes a bit line contact part.

7. The semiconductor device according to claim 1, wherein said first insulating film is a silicon nitride film and, wherein said second insulating film is a silicon oxide film.
